(19) United States
(12) Patent Application Publication
(10) Pub. No.: US 2014/0360864 A1
(43) Pub. Date: Dec. 11, 2014

(54) APPARATUS AND METHODS FOR FORMING CHALCOPYRITE LAYERS ONTO A SUBSTRATE

(71) Applicant: TSMC Solar Ltd., Taichung City (TW)

(72) Inventors: Wen-Tsai YEN, Caotun Township (TW); Chung-Hsien WU, Luzhu Township (TW); Chi-Yu CHIANG, Taoyuan City (TW); Shih-Wei CHEN, Kaohsiung City (TW); Wen-Chin LEE, Baoshan Township (TW)

(21) Appl. No.: 13/912,263

(22) Filed: Jun. 7, 2013

(51) Int. Cl. H01L 31/18

(52) U.S. Cl. CPC H01L 31/18
USPC 204/192.25; 204/298.09

(57) ABSTRACT

A method generally comprises providing heat to a substrate in at least one buffer chamber and transferring the substrate to at least one deposition chamber that is coupled to the buffer chamber via an conveyor. The method also includes depositing a first set of a plurality of elements, using sputtering, and a second set of a plurality of elements, using evaporation, onto at least a portion of the substrate in the deposition chamber.

### FIELD

The disclosed apparatus and method relate to the formation of chalcopyrite layers onto a substrate that can be useful in manufacturing photovoltaic cells.

### BACKGROUND

Photovoltaic cells or solar cells are photovoltaic components for direct generation of electrical current from sunlight. Due to the growing demand for clean sources of energy, the manufacture of solar cells has expanded dramatically in recent years and continues to expand. Various types of solar cells exist and continue to be developed. A variety of solar energy collecting modules currently exists. The solar energy collecting modules generally include large, flat substrates and include a back contact layer, an absorber layer, a buffer layer, and a front contact layer.

A plurality of solar cells are formed on one substrate, and are connected in series by respective interconnect structures in each solar cell to form a solar cell module. The absorber layer absorbs the sunlight that is converted into electrical current using the back contact layer. As such, semi-conductive materials are used in the manufacturing or fabrication of at least some known solar cells by being used as the material to form the absorber layer. More specifically, chalcopyrite based semi-conductive materials, such as copper indium gallium (di)selenide (CIGS), are used to form the absorber layer that is deposited onto the substrate. At least some known techniques that are used for CIGS deposition include, for example, co-evaporation and selenization of metal precursors.

However, there can be challenges and limitations in using such techniques. For example, when using co-evaporation, it can be difficult to uniformly evaporate metal elements, such as copper, indium, and gallium, over a wide area. Moreover, the melting point of copper is relatively high at about 1084° C. Such a relatively high temperature can result in substantially high process costs and the temperature of the substrate can be adversely affected. As such, there are limitations with respect to commercialization when using co-evaporation for CIGS deposition. Moreover, when using such techniques, contamination of the sputtering metal targets can occur due to the generation of selenium and/or sulfur vapor during the process or due to the formation of toxic gases, such as hydrogen selenide or hydrogen sulfide.

### BRIEF DESCRIPTION OF THE FIGURES

FIG. 1 is a cross-sectional view of an exemplary solar cell that includes a substrate and a chalcopyrite absorber layer.

FIG. 2 is a block diagram of an exemplary apparatus used for forming the chalcopyrite layer onto the substrate of the solar cell shown in FIG. 1.

FIG. 3 is a flow diagram of an exemplary method for forming the chalcopyrite layer onto the substrate using the apparatus shown in FIG. 2.

FIG. 4 is a block diagram of an alternative apparatus used for forming the chalcopyrite layer onto the substrate of the solar cell shown in FIG. 1.

FIG. 5 is a flow diagram of an exemplary method for forming the chalcopyrite layer onto the substrate using the apparatus shown in FIG. 4.

FIG. 6 is a block diagram of another alternative apparatus used for forming the chalcopyrite layer onto the substrate of the solar cell shown in FIG. 1.

FIG. 7 is a flow diagram of an exemplary method for forming the chalcopyrite layer onto the substrate using the apparatus shown in FIG. 6.

### DETAILED DESCRIPTION

In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

This description of the exemplary embodiments is intended to be read in connection with the accompanying drawings, which are to be considered part of the entire written description. The drawings are not drawn to scale. In the various drawings, like reference numerals indicate like items, unless expressly indicated otherwise in the text.

The exemplary apparatus and methods described herein overcome at least some disadvantages of other techniques that are used for the formation of a chalcopyrite based semi-conductive layer, such as copper indium gallium (di)selenide (CIGS), onto a substrate by providing an apparatus and method that facilitates a hybrid in-line sputtering process, along with an evaporation process. More specifically, a substrate is initially prepared for the process within a buffer chamber by being heated within the buffer chamber, for example. The substrate is then transferred to at least one deposition chamber that is coupled to the buffer chamber via, for example, an conveyor. In the deposition chamber, a first set of a plurality of elements that include, for example, copper, zinc, indium, aluminum, gold, and/or tin, are deposited onto at least a portion of the substrate using sputtering, while a second set of a plurality of elements that include, for example, gallium, selenium, sulfur, and/or sodium, are deposited onto at least a portion of the substrate using evaporation. More specifically, the first set of elements are metallic targets and the sputtering is utilized to provide the targets with the second set of elements by evaporation. As such, a chalcopyrite film or layer can be formed on the substrate. By using sputtering, along with evaporation, in the deposition chamber, there can be a substantially complete mixing or combining of each of the absorber components. Moreover, such a technique enables a relatively large volume production that can readily be scaled to a higher volume.

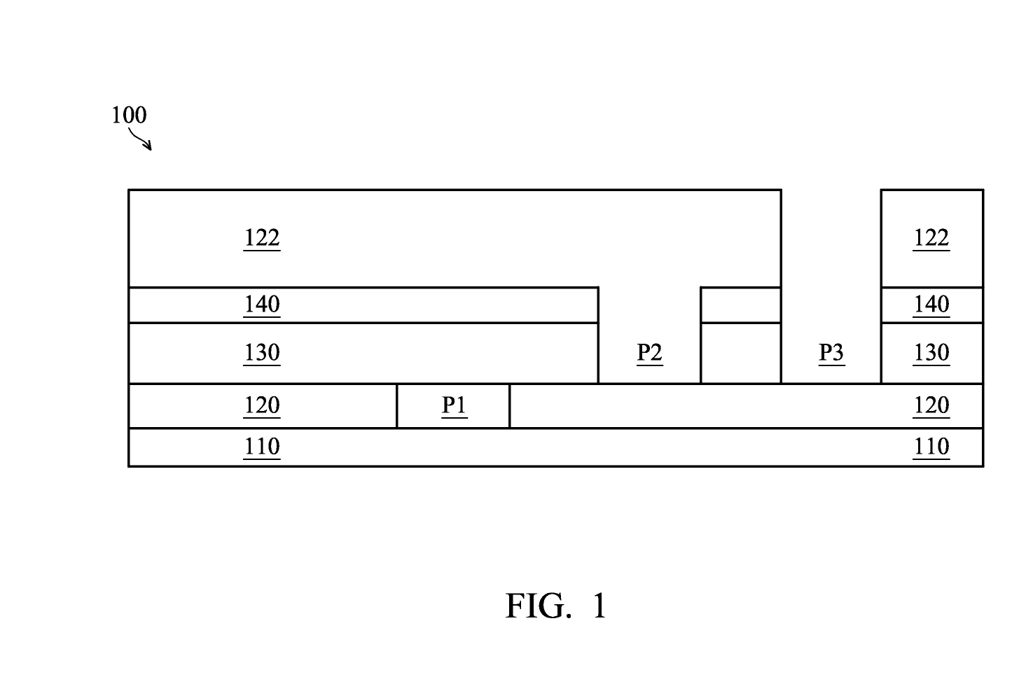

FIG. 1 illustrates an exemplary solar cell 100 that includes a substrate 110 having a back contact layer 120 and front contact layer 122. An absorber layer 130 is on back contact layer 120 and a buffer layer 140 is on absorber layer 130. Front contact layer 122 is above buffer layer 140. In some embodiments, substrate 110 is a glass substrate, such as soda lime glass. In other embodiments, substrate 110 is a flexible metal foil or polymer (e.g., polyimide). In some embodiments, substrate 110 has a thickness in a range from about 0.1 mm to about 5 mm.

In some embodiments, back contact layer 120 is formed of molybdenum above which absorber layer 130 can be formed. In some embodiments, back contact layer 120 is formed by sputtering. Other embodiments include other suitable back contact materials, such as platinum, gold, silver, or copper, instead of molybdenum. For example, in some embodiments, a back contact layer of copper or nickel is provided, above which a cadmium telluride absorber layer can be formed. Following formation of the back contact layer 120, a P1 scribe line is formed in back contact layer 120 and is filled with the absorber layer material. In some embodiments, back contact 120 has a thickness from about 10 μm to about 300 μm.

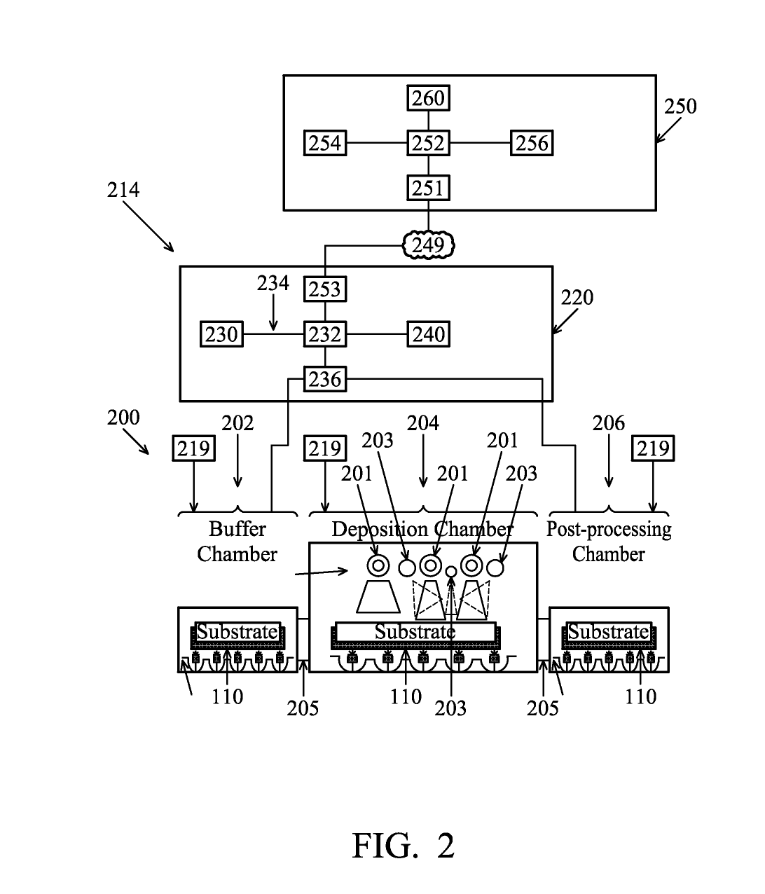

Absorber layer 130 is formed on back contact layer 120. In the exemplary embodiment, absorber layer 130 has a thickness of about 1 micrometer or more and is a chalcopyrite-based absorber layer comprising CIGS. As described in more detail below with respect to FIGS. 2-7, absorber layer 130 is deposited onto back contact layer 120 by using a hybrid in-line sputtering process, along with an evaporation process. In some embodiments, buffer layer 140 can be one of the group consisting of CdS, ZnS, In2S3, In2Se3, and Zn1-xMgxO, (e.g., ZnO). Other suitable buffer layer materials can be used. In some embodiments, buffer layer 140 has a thickness from about 1 nm to about 500 nm.

FIG. 2 illustrates an apparatus 200 that can be used for the formation of the chalcopyrite based semi-conductive absorber layer 130 (shown in FIG. 1) onto substrate 110. In the exemplary embodiment, apparatus 200 includes a buffer chamber 202 that is configured to receive substrate 110 and to prepare substrate 110 therein for further processing. For example, buffer chamber 202 can include a vacuum (not shown), a heater (not shown), and/or a heat exchanger (not shown) to facilitate providing heat energy to substrate 110 such that substrate is heated and ready to undergo further processing. A deposition chamber 204 is coupled to buffer chamber 202, via, for example, an endless conveyor 205, and deposition chamber 204 is configured to receive substrate 110 from buffer chamber 202 via endless conveyor 205.

In some embodiments, deposition chamber 204, is configured to facilitate sputtering and evaporation therein. For example, deposition chamber 204 can be configured to facilitate radio frequency (RF) sputtering, alternating current (AC) sputtering, and pulsed direct current mode (PDC) sputtering. As such, deposition chamber 204 can include a wave generator (not shown) that is configured to transmit at least one radio frequency wave through an inert gas, for example, to generate positive ions. For example, deposition chamber 204 can be configured to facilitate evaporation, which consists of utilize a RF, IBAD or Microwave-cracked Se radicals instead of conventional vaporized Se for dissociation for enhanced incorporation function in the same chamber. In some embodiments, deposition chamber 204 can also include a vacuum pump or vacuum port (not shown), a heater (not shown), and/or a heat exchanger (not shown) to facilitate evaporation therein. In some embodiments, deposition chamber 204 is configured to deposit a first set of a plurality of elements 201 and a second set of a plurality of elements 203 via sputtering and evaporation, respectively, onto at least a portion of substrate 110 to form semi-conductive absorber layer 130 on substrate 110. In some embodiments, the first set of elements 201 includes copper, zinc, indium, aluminum, gold, and/or tin and the second set of elements 203 includes gallium, selenium, sulfur, and/or sodium.

Apparatus 200 also includes a post-processing chamber 206 that is coupled to deposition chamber 204 via endless conveyor 205. In some embodiments post-processing chamber 206 is configured to conduct a cooling and/or annealing of the formed absorber layer 130 on substrate 110. For example, post-processing chamber 206 can include a cooling flow device, such as a fan, that is positioned proximate to layer 130 on substrate 110, such that air flow can be directed onto layer 130 and substrate 110. Post-processing chamber 206 can also include inert gas, selenium, sulfur, and/or sulfur (chalcogen) for annealing of the formed absorber layer 130 on substrate 110.

In some embodiments, a control system 214 is coupled to apparatus 200, and control system 214 is configured to control various operational parameters, such as temperature and pressure, within apparatus 200. In some embodiments, control system 214 includes a controller 220 that is operatively coupled to vary the operation of apparatus 200 as a function of values determined from sensors responsive to parameters such as temperature and pressure, as well as rates of change of such parameters, according to a programmed control scheme or algorithm. More specifically, in some embodiments, controller 220 is coupled to at least one valve (not shown) in buffer chamber 202, at least one valve (not shown) in deposition chamber 204, and at least one valve (not shown) in post-processing chamber 206, for example.

In some embodiments, controller 220 is enabled to facilitate operative features of each of the valves, via features that include, without limitation, receiving inputs, transmitting outputs, and transmitting opening and closing commands. As such, controller 220 is enabled to independently control the pressure within each of the buffer chamber 202, deposition chamber 204, and post-processing chamber 206, for example. Similarly, controller 220 can be coupled to the heat exchanger in buffer chamber 202, the heat exchanger in deposition chamber 204, and the cooling apparatus in post-processing chamber 206, for example, such that controller 220 is enabled to facilitate operative features of each of the heat exchangers and/or the cooling apparatus. As such, controller 220 is enabled to independently control the temperature within each of the buffer chamber 202, deposition chamber 204, and post-processing chamber 206, for example.

In some embodiments, controller 220 can be a real-time controller and can include any suitable processor-based or microprocessor-based system, such as a computer system, that includes microcontrollers, reduced instruction set circuits (RISC), application-specific integrated circuits (ASICs), logic circuits, and/or any other circuit or processor that is capable of executing the functions described herein. In one embodiment, controller 120 can be a microprocessor that includes read-only memory (ROM) and/or random access memory (RAM), such as, for example, a 32 bit microcomputer with 2 Mbit ROM and 64 Kbit RAM. As used herein, the term “real-time” refers to outcomes occurring in a substantially short period of time after a change in the inputs affect the outcome, with the time period being a design parameter that can be selected based on the importance of the outcome and/or the capability of the system processing the inputs to generate the outcome.

In some embodiments, controller 220 includes a memory device 230 that stores executable instructions and/or one or more operating parameters representing and/or indicating an operating condition of buffer chamber 202, deposition chamber 204, and post-processing chamber 206. Controller 220 also includes a processor 232 that is coupled to memory device 230 via a system bus 234. In some embodiments, processor 232 can include a processing unit, such as, without limitation, an integrated circuit (IC), an application specific integrated circuit (ASIC), a microcomputer, a programmable logic controller (PLC), and/or any other programmable circuit. Alternatively, processor 232 can include multiple processing units (e.g., in a multi-core configuration). The above examples are exemplary only, and thus are not intended to limit in any way the definition and/or meaning of the term “processor.”

Moreover, in some embodiments, controller 220 includes a control interface 236 that is coupled to buffer chamber 202, deposition chamber 204, and post-processing chamber 206. More specifically, control interface 236 is coupled to components, such as the valves, heat exchangers, and/or cooling apparatus within buffer chamber 202, deposition chamber 204, and post-processing chamber 206, and control interface 136 is configured to control an operation of the valves, heat exchangers, and/or cooling apparatus. For example, processor 232 can be programmed to generate one or more control parameters that are transmitted to control interface 236. Control interface 236 can then transmit a control parameter to modulate, open, or close the valves, for example.

Various connections are available between control interface 236 and buffer chamber 202, deposition chamber 204, and post-processing chamber 206. Such connections can include, without limitation, an electrical conductor, a low-level serial data connection, such as Recommended Standard (RS) 232 or RS-485, a high-level serial data connection, such as USB, a field bus, a PROFIBUS®, or Institute of Electrical and Electronics Engineers (IEEE) 1394 (a/k/a FIREWIRE), a parallel data connection, such as IEEE 1284 or IEEE 488, a short-range wireless communication channel (personal area network) such as BLUETOOTH, and/or a private (e.g., inaccessible outside system) network connection, whether wired or wireless. PROFIBUS is a registered trademark of Profibus Trade Organization of Scottsdale, Ariz. IEEE is a registered trademark of the Institute of Electrical and Electronics Engineers, Inc., of New York, N.Y. BLUETOOTH is a registered trademark of Bluetooth SIG, Inc. of Kirkland, Wash.

In some embodiments, control system 214 also includes sensors 219 that are coupled to buffer chamber 202, deposition chamber 204, and post-processing chamber 206. More specifically, in some embodiments, controller 220 includes a sensor interface 240 that is coupled to sensors 219. In some embodiments, sensors 219 are configured to detect various operating parameters, such as temperature and/or pressure, within each of the buffer chamber 202, deposition chamber 204, and post-processing chamber 206. Sensors 219 each transmit a signal corresponding to their respective detected parameters to controller 220. Sensors 219 can each transmit a signal continuously, periodically, or only once, for example. In other embodiments, different bases are used for signal timings. Furthermore, sensors 219 can each transmit a signal either in an analog form or in a digital form. Various connections are available between sensor interface 240 and sensors 219. Such connections can include, without limitation, an electrical conductor, a low-level serial data connection, such as RS 232 or RS-485, a high-level serial data connection, such as USB or IEEE® 1394, a parallel data connection, such as IEEE® 1284 or IEEE® 488, a short-range wireless communication channel such as BLUETOOTH®, and/or a private (e.g., inaccessible outside system) network connection, whether wired or wireless.

Control system 214 can also include a user computing device 250 that is coupled to controller 220 via a network 249. More specifically, computing device 250 includes a communication interface 251 that is coupled to a communication interface 253 contained within controller 220. User computing device 250 includes a processor 252 for executing instructions. In some embodiments, executable instructions are stored in a memory device 254. Processor 252 can include one or more processing units (e.g., in a multi-core configuration). Memory device 254 is any device allowing information, such as executable instructions and/or other data, to be stored and retrieved. User computing device 250 also includes at least one media output component 256 for use in presenting information to a user. Media output component 256 is any component capable of conveying information to the user. Media output component 256 can include, without limitation, a display device (not shown) (e.g., a liquid crystal display (LCD), an organic light emitting diode (OLED) display, or an audio output device (e.g., a speaker or headphones)).

Moreover, in some embodiments, user computing device 250 includes an input interface 260 for receiving input from a user. Input interface 260 can include, for example, a keyboard, a pointing device, a mouse, a stylus, a touch sensitive panel (e.g., a touch pad or a touch screen), a gyroscope, an accelerometer, a position detector, and/or an audio input device. A single component, such as a touch screen, can function as both an output device of media output component 256 and input interface 260.

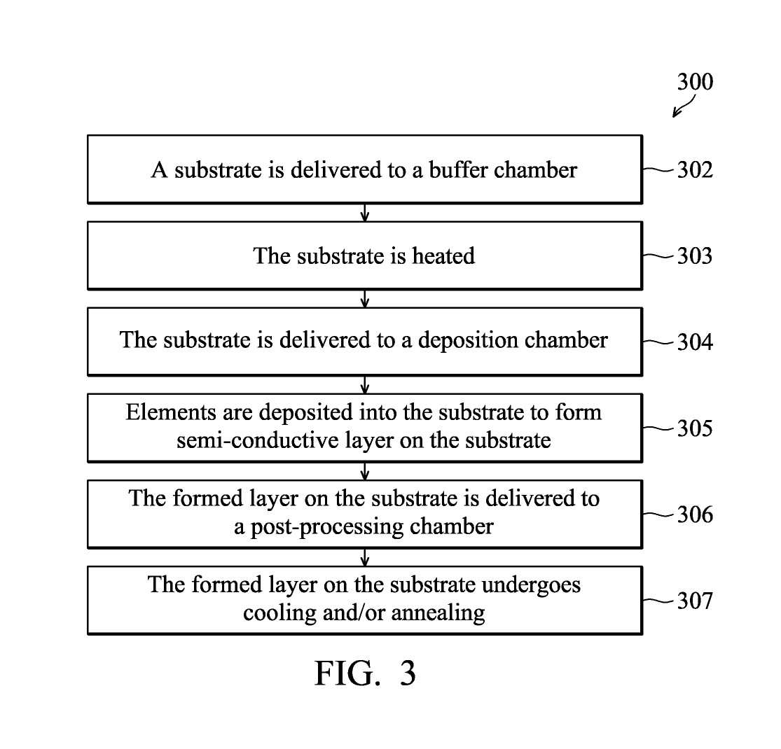

FIG. 3 is a flow diagram 300 of an exemplary method for forming a semi-conductive layer, such as absorber layer 130 (shown in FIG. 1) onto a substrate, such as substrate 110 (shown in FIGS. 1, 2, 4, and 6), using apparatus 200 (shown in FIG. 2). In step 302, substrate 110 is delivered to buffer chamber 202 (shown in FIG. 2) via endless conveyor 205 (shown in FIG. 2). In step 303, substrate 110 is heated within buffer chamber 202 in preparation for further processing. In step 304, substrate 110 is conveyed on endless conveyor 205 from buffer chamber 202 to deposition chamber 204 (shown in FIG. 2).

In step 305, a first set of elements 201 (shown in FIG. 2) that include, for example, copper, zinc, indium, aluminum, gold and/or tin, are deposited onto at least a portion of substrate 110 using sputtering, while a second set of elements 203 (shown in FIG. 2) that include gallium, selenium, sulfur, and/or sodium, for example, are deposited onto at least a portion of substrate 110 using evaporation to form semi-conductive absorber layer 130 (shown in FIG. 1) on substrate 110. More specifically, in some embodiments, first set of elements 201 (i.e., the copper, zinc indium, aluminum, gold, and/or tin) are metallic targets and the sputtering is utilized to provide the targets with the gallium, selenium, sulfur, and/or sodium by evaporation. The deposition of first set of element 201 using sputtering and the second set of elements 203 using evaporation is performed at room temperature or at a temperature range of between about 200° C. to about 650° C. Preferably, the deposition, in some embodiments, is performed at either room temperature or at a temperature range of between about 450° C. to about 650° C. Moreover, the deposition of metal elements in the first and second set of elements can be done simultaneously or sequentially. For example, in one embodiment, copper and indium can be deposited simultaneously onto substrate 110 via sputtering, along with gallium and selenium via evaporation. Alternatively, copper can be deposited onto substrate 110 via sputtering along with selenium via evaporation first. Then, indium can be deposited via sputtering along with gallium via evaporation. Moreover, in some embodiments, the sputtering and evaporation rates can vary throughout the deposition process or remain constant, wherein the rates can be controlled by, for example, control system 214 (shown in FIG. 2). Similarly, the temperature within deposition chamber 204 can remain constant or vary throughout the deposition process, wherein the temperature can also be controlled by control system 214.

When deposition is performed, layer 130 is formed on substrate 110. In step 306, layer 130 that is formed on substrate 110 is delivered to post-processing chamber 206 (shown in FIG. 2). In step 307, the layer 130 formed on substrate 110 undergoes cooling and/or annealing in post-processing chamber 206 by using the cooling device (not shown) therein or by using inert gas atmosphere with or without selenium, sulfur, and/or sulfur (chalcogen), for example. In some embodiments, by using sputtering, along with evaporation, in deposition chamber 204 to form absorber layer 130 onto substrate 110, there can be a substantially complete mixing or combining of each of the absorber components (i.e., elements 201 and 203). Moreover, there can be a relatively large volume production that can readily be scaled to a higher volume.

Further, in some embodiments, operational parameters within each of buffer chamber 202, deposition chamber 204, and post-processing chamber 206 can each be controlled independently via control system 214. More specifically, a user can initially input a predefined threshold value for an operational parameter for each of buffer chamber 202, deposition chamber 204, and post-processing chamber 206 prior to step 302. For example, a user can initially input a predefined value for a temperature or a pressure for each of buffer chamber 202, deposition chamber 204, and post-processing chamber 206 via input interface 260 (shown in FIG. 2). The predefined value can be programmed with user computing device 250 and/or controller 220. As such, during operation of apparatus 200 and each of the chambers therein, the parameters, such as temperature and pressure, within each of the buffer chamber 202, deposition 204, and post-processing chamber 206 can be detected by sensors 219 coupled within each respective chamber. Sensor 219 then transmit signal(s) representative of the detected parameter values to controller 220 (shown in FIG. 2).

Depending on whether the detected value is less than, greater than, or equal to the predefined values for each of buffer chamber 202, deposition chamber 204, and post-processing chamber 206, controller 220 can transmit a control parameter to each of the buffer chamber 202, deposition chamber 204, and post-processing chamber 206. For example, in some embodiments, if the temperature within deposition chamber 204 exceeds the predefined temperature value, controller 220 will transmit a control parameter to, for example, a heat exchanger (not shown) within deposition chamber 204 or heater (not shown) within deposition chamber 204 such that the temperature can be substantially reduced to the predefined temperature value. Similarly, if the pressure within post-processing chamber 206 exceeds the predefined pressure value, then controller 220 will transmit a control parameter to, for example, a valve (not shown) within post-processing chamber 206 such that fluid flow within chamber 206 is controlled to facilitate substantially reducing the pressure therein to the predefined pressure value.

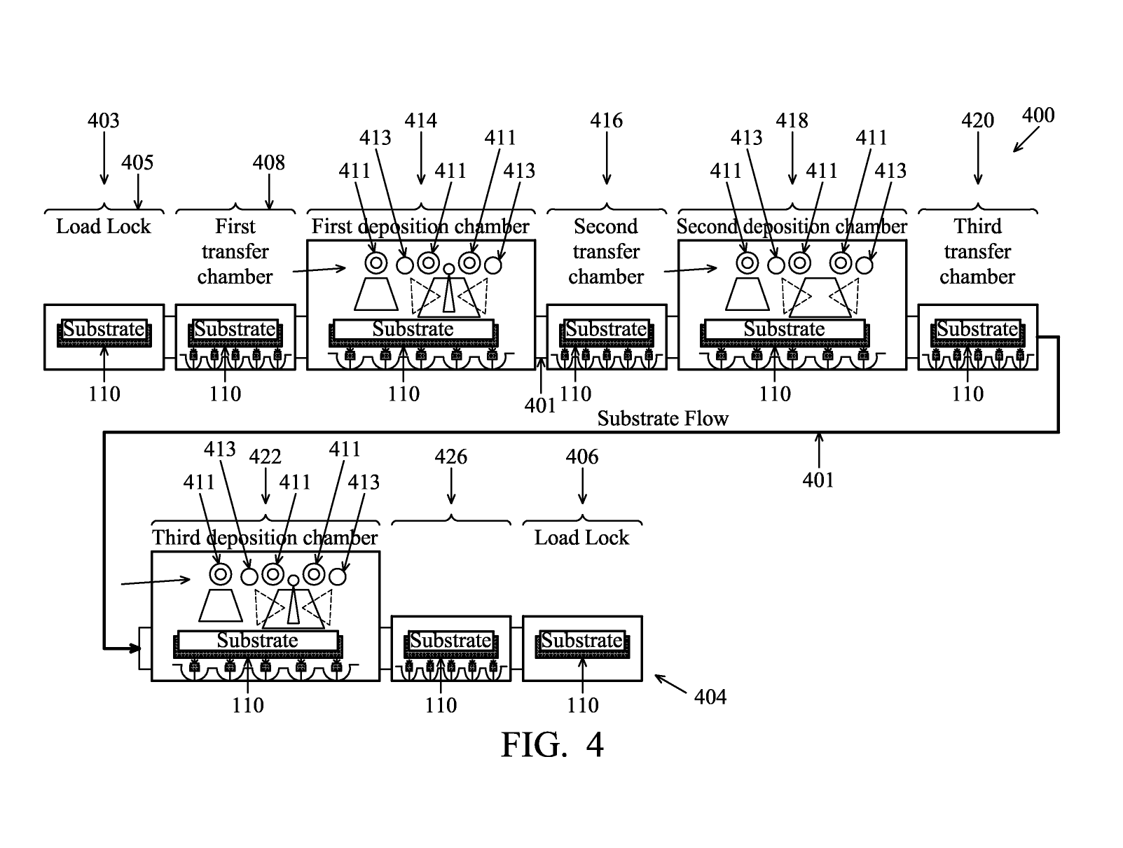

FIG. 4 illustrates an embodiment of an apparatus 400 that can be used in place of apparatus 200 (shown in FIG. 2). In some embodiments, apparatus 400 includes an endless conveyor 401 having a first end portion 403 and a second end portion 404. Apparatus 400 also includes at least two load locks or containers 405 and 406 such that one load lock 405 is positioned on first end portion 403 of endless conveyor 401 and the other load lock 406 is positioned on second end portion 404 of conveyor 401. In some embodiments, each load lock 405 and 406 are configured to deliver a substrate, such as substrate 110, from one environment to another environment. For example, load lock 405 is configured to deliver substrate 110 from the atmosphere environment to the process environment. In some embodiments, load lock 405 is coupled to a first buffer or transfer chamber 408 via conveyor 401. First transfer chamber 408 is configured to receive substrate 110 and to prepare substrate 110 for further processing, such as by heating substrate 110 therein. For example, transfer chamber 408 can include a vacuum (not shown), a heater (not shown), and/or a heat exchanger (not shown).

A first deposition chamber 414 is coupled to first transfer chamber 408, via, for example, conveyor 401, and first deposition chamber 414 is configured to receive substrate 110 from first transfer chamber 408 via conveyor 401. Deposition chamber 414, in some embodiments, is configured to facilitate sputtering and evaporation therein. For example, first deposition chamber 414 can be configured to facilitate radio frequency (RF) sputtering. As such, first deposition chamber 414 can include a wave generator (not shown) that is configured to transmit at least one energetic wave through, for example, an inert gas to generate positive ions. In some embodiments, first deposition chamber 414 can also include a vacuum (not shown), a heater (not shown), and/or a heat exchanger (not shown). In some embodiments, first deposition chamber 414 is configured to deposit at least a portion of a first set of a plurality of elements 411 and at least a portion of a second set of a plurality of elements 413 via sputtering and evaporation, respectively, onto at least a portion of substrate 110 to form at least a portion of semi-conductive absorber layer 130 (shown in FIG. 1) on substrate 110. In some embodiments, first set of elements 411 includes copper, zinc, indium, aluminum, gold, and/or tin and second set of elements 413 includes gallium, selenium, sulfur, and/or sodium.

Apparatus 400 also includes a second transfer chamber 416 that is coupled to first deposition chamber 414 via conveyor 401, wherein second transfer chamber 416 is configured to receive substrate 110 from first transfer chamber 414 via conveyor 401. In some embodiments, second transfer chamber 416 is configured to receive substrate 110, along with the newly formed layer, and to prepare the substrate and the newly formed layer for further processing. For example, second transfer chamber 416 can also include a vacuum (not shown), a heater (not shown), and/or a heat exchanger (not shown). As such, heat energy can be provided to substrate 110 and the newly formed layer such that they are prepared for further processing.

A second deposition chamber 418 is coupled to second transfer chamber 416 via conveyor 401, and second deposition chamber 418 is configured to receive substrate 110 with the newly formed layer from second transfer chamber 416 via conveyor 401. Second deposition chamber 418, in some embodiments, is also configured to facilitate sputtering and evaporation therein. In embodiments, second deposition chamber 418 is configured to deposit at least a portion of the first set of elements 411 and at least portion of the second set of elements 413 via sputtering and evaporation, respectively, onto at least a portion of substrate 110 to form at least a portion of semi-conductive absorber layer 130 on substrate 110.

In some embodiments, a third transfer chamber 420 is coupled to second deposition chamber 418 via conveyor 401 and is configured to receive substrate 110 and the recently formed layer from second deposition chamber 418 via conveyor 401. In some embodiments, third transfer chamber 420 is configured prepare substrate 110 and the recently formed layer for further processing. For example, third transfer chamber 420 can also include a vacuum (not shown), a heater (not shown), and/or a heat exchanger (not shown). As such, heat energy can be provided to substrate 110 and the recently formed layer.

A third deposition chamber 422 is coupled to third transfer chamber 420 via conveyor 401, and third deposition chamber 422 is configured to receive substrate 110 and the recently formed layer from third transfer chamber 420 via conveyor 401. In some embodiments, third deposition chamber 422 is also configured to facilitate sputtering and evaporation therein. In some embodiments, third deposition chamber 422 is configured to deposit at least a portion of the first set of elements 411 and at least a portion of the second set of elements 413 via sputtering and evaporation, respectively, onto at least a portion of substrate 110 to form at least a portion of semi-conductive absorber layer 130 on substrate 110.

A post-processing chamber 426 is coupled to third deposition chamber 422 via conveyor 401. In some embodiments post-processing chamber 426 is configured to conduct a cooling and/or annealing of the formed absorber layer 130 on substrate 110. For example, post-processing chamber 426 can include, for example, a cooling flow device, such as a fan, that is positioned proximate to layer 130 on substrate 110 such that air flow can be directed onto layer 130 and substrate 110. Post-processing chamber 426 can also include inert gas, selenium, sulfur, and/or sulfur (chalcogen) for annealing of the formed absorber layer 130 on substrate 110.

Although three deposition chambers and three transfer chambers are illustrated in FIG. 4 for apparatus 400, any number of deposition and transfer chambers can be included for apparatus 400. For example, apparatus 400 can include four deposition chambers that include one transfer chamber between each of the deposition chambers.

Moreover, in some embodiments, a control system, such as control system 214 (shown in FIG. 2) is coupled to apparatus 400 such that control system 214 is enabled to control various operational parameters, such as temperature and pressure, within apparatus 400. More specifically, control system 214 is configured to control various operational parameters, such as temperature and pressure, within each of the chambers for apparatus 400 independently. For example, controller 220 (shown in FIG. 2) can be coupled to at least one valve (not shown) within each chamber of apparatus 400, for example. As described above, controller 220 is enabled to facilitate operative features of each of the valves, via features that include, without limitation, receiving permissive inputs, transmitting permissive outputs, and transmitting opening and closing commands. As such, controller 220 is enabled to control, for example, the pressure within each of the chambers independently. Similarly, controller 220 can be coupled to, for example, the heater, the heat exchanger, and/or the cooling apparatus in each of the chambers of apparatus 400 such that controller 220 is enabled to facilitate operative features of the heaters, the heat exchangers, and/or the cooling apparatus. As such, controller 220 is enabled to control, for example, the temperature within each of the chambers independently.

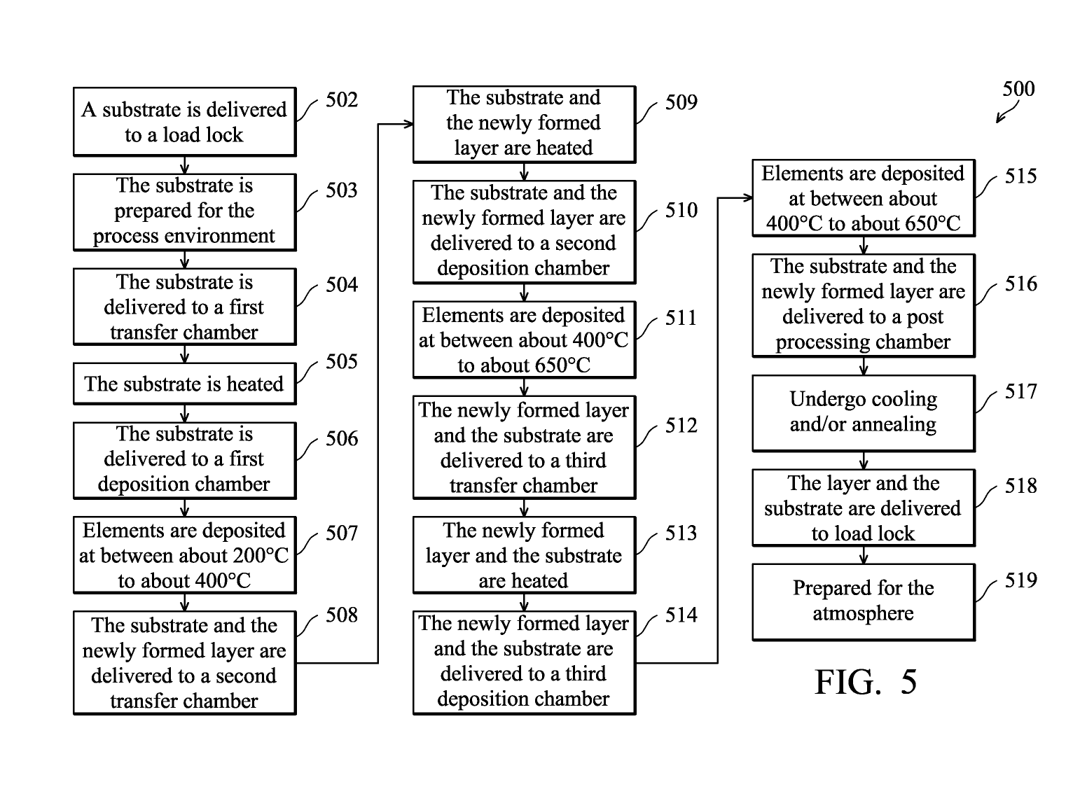

FIG. 5 is a flow diagram 500 of an exemplary method for forming semi-conductive materials onto a substrate, such as substrate 110 (shown in FIGS. 1, 2, 4, and 6) using apparatus 400 (shown in FIG. 4). In step 502, substrate 110 is delivered to load lock 405 (shown in FIG. 4). In step 503, substrate 110 is prepared for the process environment in load lock 405. In step 504, substrate 110 is delivered from load lock 405 to first buffer or transfer chamber 408 (shown in FIG. 4). In step 505, substrate 110 is heated within first transfer chamber 408 in preparation for further processing. In step 506, substrate 110 is delivered from first transfer chamber 408 to first deposition chamber 414 (shown in FIG. 4).

When substrate 110 is in first deposition chamber 414, at least a portion of the first set of elements 411 are deposited onto at least a portion of substrate 110 using sputtering, while at least a portion of the second set of elements 413 are deposited onto at least a portion of substrate 110 using evaporation to form at least a portion of semi-conductive layer 130 (shown in FIG. 1) on substrate 110. In some embodiments, in step 507, first set of elements 411 zinc, indium, aluminum, and/or tin are deposited onto at least a portion of substrate 110 using sputtering, and second set of elements 413 gallium, selenium, sulfur, and/or sodium are deposited onto at least a portion of substrate 110 using evaporation, wherein the deposition of elements 411 and 413 is performed in first deposition chamber at a temperature range of between about between about 200° C. to about 400° C. More specifically, in some embodiments, zinc, indium, aluminum, and/or tin are metallic targets and the sputtering is utilized to provide the targets with the gallium, selenium, sulfur, and/or sodium by evaporation. Moreover, the deposition of metal elements in the first and second set of elements can be done simultaneously or sequentially. For example, in one embodiment, zinc and indium can be deposited simultaneously onto substrate 110 via sputtering, along with gallium and selenium via evaporation. Alternatively, zinc can first be deposited onto substrate 110 via sputtering along with selenium via evaporation, and then indium can be deposited next via sputtering along with gallium via evaporation. Moreover, in some embodiments, the sputtering and evaporation rates can vary throughout the deposition process or remain constant, wherein the rates can be controlled by, for example, control system 214 (shown in FIG. 2). Similarly, the temperature within first deposition chamber 414 can remain constant or vary throughout the deposition process, wherein the temperature can also be controlled by control system 214.

When deposition in first deposition chamber 414 is complete, then, in step 508, substrate 110 and the newly formed layer are delivered to second transfer chamber 416 (shown in FIG. 4). In step 509, substrate 110 and the newly formed layer are heated in transfer chamber 416 so that they will be ready for further processing. In step 510, the newly formed layer and substrate 110 are delivered to second deposition chamber 418 (shown in FIG. 4).

When substrate 110 and layer 130 are in second deposition chamber 418, then at least a portion of first set of elements 411 and second set of elements 413 are deposited onto at least a portion of substrate 110 using sputtering and evaporation, respectively. More specifically, in step 511, first set of elements 411 copper and/or gold, are deposited onto at least a portion of substrate 110 using sputtering, while second set of elements 413 selenium, sulfur, and/or sodium, are deposited onto at least a portion of substrate 110 using evaporation to form at least a portion of semi-conductive layer 130 on substrate 110, wherein the deposition is performed at a temperature range of between about between about 400° C. to about 650° C. More specifically, in some embodiments, the copper and/or gold are metallic targets and the sputtering is utilized to provide the targets with the selenium, sulfur, and/or sodium by evaporation. Moreover, the deposition of metal elements in the first and second set of elements can be done simultaneously or sequentially. Indium and gallium can still deposit in second deposition chamber 418 via sputtering and evaporation as described above for step 507. Moreover, in some embodiments, the sputtering and evaporation rates can vary throughout the deposition process or remain constant, wherein the rates can be controlled by, for example, control system 214. Similarly, the temperature within second deposition chamber 418 can remain constant or vary throughout the deposition process, wherein the temperature can also be controlled by control system 214.

When deposition in second deposition chamber 418 is complete, then, in step 512, the newly formed layer and substrate 110 are delivered to third transfer chamber 420 (shown in FIG. 4). In step 513, the newly formed layer and substrate 110 are heated in transfer chamber 420 so that they will be ready for further processing. In step 514, the newly formed layer and substrate 110 are delivered to third deposition chamber 422 (shown in FIG. 4) via conveyor 401.

When substrate 110 and the newly formed layer are in third deposition chamber 422, then, at least a portion of first and second set of elements 411 are deposited onto substrate 110 using sputtering and evaporation, respectively. In some embodiments, in step 515, first set of elements 411 indium, aluminum, tin, and zinc, are deposited onto at least a portion of substrate 110 using sputtering, while second set of elements 413 gallium, selenium, sulfur, and/or sodium, are deposited onto at least a portion of substrate 110 using evaporation to form at least a portion of semi-conductive layer 130 on substrate 110, wherein the deposition is performed at a temperature range of between about between about 400° C. to about 650° C. More specifically, in some embodiments, the indium, aluminum, tin, and zinc are metallic targets and the sputtering is utilized to provide the targets with the gallium, selenium, sulfur, and/or sodium by evaporation. Moreover, the deposition of metal elements in first and second set of elements 411 and 413, respectively, can be done simultaneously or sequentially. In some embodiments, the absorber layer 130 is completely formed onto substrate 110 after step 515. Moreover, in some embodiments, the sputtering and evaporation rates can vary throughout the deposition process or remain constant, wherein the rates can be controlled by, for example, control system 214. Similarly, the temperature within third deposition chamber 422 can remain constant or vary throughout the deposition process, wherein the temperature can also be controlled by control system 214.

In step 516, absorber layer 130 and substrate 110 are delivered to post-processing chamber 426 (shown in FIG. 4). In step 517, absorber layer 130 and substrate 110 undergo cooling and/or annealing in post-processing chamber 426, wherein post-processing chamber 426 uses inert gas atmosphere with or without selenium, sulfur, and/or sulfur (chalcogen). In some embodiments, hydrogen gas can also be added to post-processing chamber 426 for the annealing. While some embodiments show post-processing chamber 426 using selenium, sulfur, hydrogen gas, and/or sulfur (chalcogen), it should be noted that any of the transfer chambers for apparatus 400 can also use such components to control the atmosphere within each of the chambers. Layer 130 on substrate 110 can then be delivered to load lock 406 in step 518, wherein layer 130 on substrate 110 can be prepared for the atmosphere in step 519.

Moreover, in some embodiments, operational parameters within each of the chambers of apparatus 400 can be controlled independently via control system 214. More specifically, a user can initially input a predefined threshold value for an operational parameter for each of the chambers. For example, a user can initially input a predefined threshold value for a temperature or a pressure for each of the chambers via input interface 260 (shown in FIG. 2). The predefined threshold value can be programmed with user computing device 250 and/or controller 220. As such, during operation of apparatus 400 and each of the chambers therein, the parameters, such as temperature and pressure, within each of the chambers can be detected by sensors (not shown) coupled within each respective chamber. The sensors then transmit signal(s) representative of the detected parameter values to controller 220 (shown in FIG. 2).

Depending on whether the detected value is less than, greater than, or equal to the predefined threshold values for each of the chambers in apparatus 400, controller 220 will transmit a control parameter to each of the chambers. For example, in some embodiments, if the temperature within first deposition chamber 414 exceeds the predefined temperature value, controller 220 will transmit a control parameter to, for example, a heat exchanger (not shown) within deposition chamber 414 or heater (not shown) within deposition chamber 414 such that the temperature can be substantially reduced to the predefined temperature value. Similarly, if the pressure within, for example, second transfer chamber 416 exceeds the predefined pressure value, controller 220 will transmit a control parameter to, for example, a valve (not shown) within transfer chamber 416 to control the fluid flow within transfer chamber 416 and/or use selenium, sulfur, hydrogen gas, and/or sulfur (chalcogen) to control the pressure within transfer chamber 416.

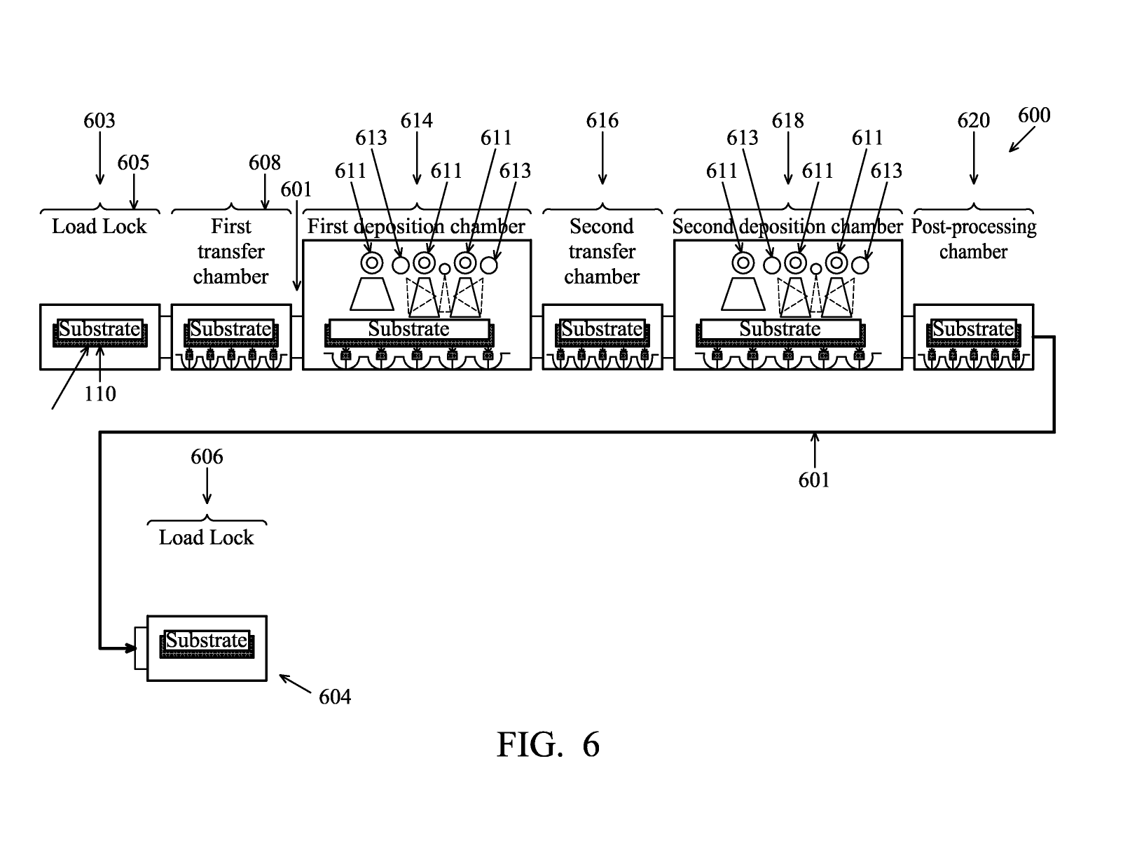

FIG. 6 illustrates an apparatus 600 that can be used in place of apparatus 200 (shown in FIG. 2) or apparatus 400 (shown in FIG. 4). In some embodiments, apparatus 600 includes a conveyor 601 having a first end portion 603 and a second end portion 604. Apparatus 600 also includes at least two load locks or containers 605 and 606 such that one load lock 605 is positioned on first end portion 603 of conveyor 601 and the other load lock 606 is positioned on second end portion 604 of conveyor 601. In some embodiments, each load lock 605 is configured to deliver a substrate, such as substrate 110, from one environment to another environment. For example, load lock 605 is configured to deliver substrate 110 from the atmosphere to the process environment. In some embodiments, load lock 605 is coupled to a first buffer or transfer chamber 608 via conveyor 601. First transfer chamber 608 is configured to receive substrate 110 and prepare substrate 110 for further processing. For example, transfer chamber 608 can include a vacuum (not shown), a heater (not shown), and/or a heat exchanger (not shown). As such, heat energy can be provided to substrate 110 such that substrate 110 is prepared for further processing.

A first deposition chamber 614 is coupled to first transfer chamber 608, via, for example, conveyor 601, and first deposition chamber 614 is configured to receive substrate 110 from first transfer chamber 608 via conveyor 601. Deposition chamber 614, in some embodiments, is configured to facilitate sputtering and evaporation therein. For example, first deposition chamber 614 can be configured to facilitate radio frequency (RF) sputtering. As such, first deposition chamber 614 can include a wave generator (not shown) that is configured to transmit at least one energetic wave through, for example, an inert gas to generate positive ions. In some embodiments, first deposition chamber 614 can also include a vacuum (not shown), a heater (not shown), and/or a heat exchanger (not shown) to facilitate evaporation therein. In some embodiments, first deposition chamber 614 is configured to deposit a precursor layer onto substrate layer 110 by depositing at least a portion of a first set of a plurality of elements 611 and at least portion of a second set of a plurality of elements 613 via sputtering and evaporation, respectively, onto at least a portion of substrate 110 to form at least a portion of semi-conductive absorber layer 130 (shown in FIG. 1) on substrate 110. In some embodiments, first set of elements 611 includes copper, zinc, indium, aluminum, and/or tin and second set of elements 613 includes gallium, selenium, sulfur, and/or sodium. Moreover, in some embodiments, precursor layer includes copper-rich or a copper-poor precursor layer.

Apparatus 600 also includes a second transfer chamber 616 that is coupled to first deposition chamber 614 via conveyor 601 and is configured to receive substrate 110 from first transfer chamber 614 via conveyor 601. In some embodiments, second transfer chamber 616 is configured to receive substrate 110 and the newly formed layer so that they both can be prepared for further processing. For example, second transfer chamber 616 can also include a vacuum (not shown), a heater (not shown), and/or a heat exchanger (not shown). As such, heat energy can be provided to substrate 110 such that the substrate is prepared for further processing.

A second deposition chamber 618 is coupled to second transfer chamber 616 via conveyor 601, and second deposition chamber 618 is configured to receive substrate 110 from second transfer chamber 616 via conveyor 601. Deposition chamber 618, in some embodiments, is also configured to facilitate sputtering and evaporation therein. In some embodiments, second deposition chamber 418 is configured to deposit a precursor layer onto substrate 110 by depositing at least a portion of the first set of elements 611 and at least portion of the second set of elements 613 via sputtering and evaporation, respectively, onto at least a portion of substrate 110 to form at least a portion of semi-conductive absorber layer 130 on substrate 110.

In some embodiments, a post-processing chamber 620 is coupled to second deposition chamber 618 via conveyor 601 and is configured to receive substrate 110 with the absorber layer 130 from second deposition chamber 618 via conveyor 401. In some embodiments, post-processing chamber 620, can include, for example, a cooling flow device, such as a fan, that is positioned proximate to layer 130 on substrate 110 such that air flow can be directed onto layer 130 and substrate 110. Post-processing chamber 620 can also include inert gas, selenium, sulfur, and/or sulfur (chalcogen) for annealing of the formed absorber layer 130 on substrate 110. It should be noted that while two deposition chambers and two transfer chambers are illustrated in FIG. 6 for apparatus 600, any suitable number of deposition and transfer chambers can be included for apparatus 600.

Moreover, in some embodiments, a control system, such as control system 214 (shown in FIG. 2) is coupled to apparatus 600. As such, control system 214 is configured to control various operational parameters, such as temperature and pressure, within apparatus 600. More specifically, control system 614 is configured to control various operational parameters, such as temperature and pressure, within each of the chambers for apparatus 600 independently. For example, controller 220 (shown in FIG. 2) can be coupled to, for example, at least one valve (not shown) within each chamber of apparatus 600. As described above, controller 220 is enabled to facilitate operative features of each of the valves, via features that include, without limitation, receiving permissive inputs, transmitting permissive outputs, and transmitting opening and closing commands. As such, controller 220 is enabled to independently control the pressure within each of the chambers, for example. Similarly, controller 220 can be coupled to, for example, the heat exchanger, the heater, and/or the cooling apparatus in each of the chambers of apparatus 600 such that controller 220 is enabled to facilitate operative features of each of the heat exchangers, the heaters, and/or the cooling apparatus. As such, controller 220 is enabled to control, for example, the temperature within each of the chambers independently.

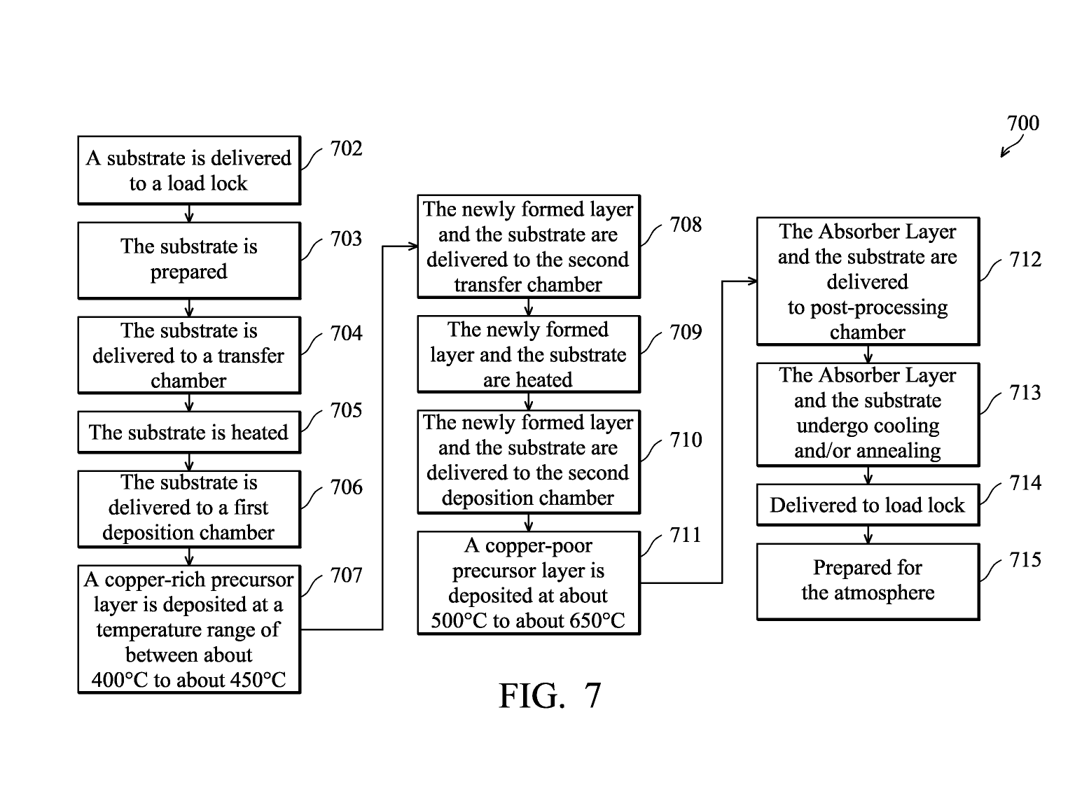

FIG. 7 is a flow diagram 700 of an exemplary method for forming semi-conductive materials onto a substrate, such as substrate 110 (shown in FIGS. 1, 2, 4, and 6) using apparatus 600 (shown in FIG. 6). In step 702, substrate 110 is delivered to load lock 605 (shown in FIG. 4). In step 703, substrate 110 is prepared for the process environment in load lock 605. In step 704, substrate 110 is delivered from load lock 405 to first buffer or transfer chamber 608 (shown in FIG. 6). In step 705, substrate 110 is heated within first transfer chamber 608 in preparation for further processing. In step 706, substrate 110 is delivered from first transfer chamber 608 to first deposition chamber 614 (shown in FIG. 6).

When substrate 110 is in first deposition chamber 614, then, in step 707, a copper-rich precursor layer is deposited onto substrate 110 using sputtering along with evaporation. More specifically, in step 707, at least a portion of first set of elements 611 (shown in FIG. 6) that include, for example, gold, copper, zinc, indium, aluminum, and/or tin, are deposited onto at least a portion of substrate 110 using sputtering, while at least a portion of second set of elements 613 (shown in FIG. 6) that include, for example, gallium, selenium, sulfur, and sodium, are deposited onto at least a portion of substrate 110 using evaporation such that a copper-rich precursor layer is deposited onto at least a portion of substrate 110. More specifically, in some embodiments, the gold, copper, zinc, indium, aluminum, and/or tin are metallic targets and the sputtering is utilized to provide the targets with the gallium, selenium, sulfur, and/or sodium by evaporation. The deposition of the copper-rich precursor layer, in step 707, is performed in first deposition chamber 614 at a temperature range of between about between about 400° C. to about 450° C. Moreover, the deposition of metal elements in the first and second set of elements can be done simultaneously or sequentially. In step 707, the sputtering and evaporation rates can vary throughout the deposition process or remain constant, wherein the rates can be controlled by, for example, control system 214 (shown in FIG. 2). Similarly, the temperature within first deposition chamber 614 can remain constant or vary throughout the deposition process in step 707, wherein the temperature can also be controlled by control system 214.

When deposition in first deposition chamber 614 is complete, then, in step 709, the newly formed layer and substrate 110 are delivered to second transfer chamber 616 (shown in FIG. 6). In step 710, the newly formed layer and substrate 110 are heated in transfer chamber 616 so that they will be ready for further processing. In step 711, the newly formed layer and substrate layer 110 are delivered to second deposition chamber 618 (shown in FIG. 6).

When substrate 110 and the newly formed layer are in second deposition chamber 618, then in step 712, a copper-poor precursor layer is deposited onto substrate 110 using sputtering along with evaporation. More specifically, at least a portion of first set of elements 611 that include, for example, gold, copper, zinc, indium, aluminum, and/or tin, are deposited onto at least a portion of substrate 110 and the copper-poor precursor layer using sputtering, while at least a portion of second set of elements 613 that include, for example, gallium, selenium, sulfur, and sodium, are deposited onto at least a portion of substrate 110 using evaporation such that a copper-poor precursor layer is deposited onto at least a portion of substrate 110. More specifically, in some embodiments, the gold, copper, zinc, indium, aluminum, and/or tin are metallic targets and the sputtering is utilized to provide the targets with the gallium, selenium, sulfur, and/or sodium by evaporation. The deposition of the copper-poor precursor layer, in step 712, is performed in first deposition chamber 614 at a temperature range of between about between about 500° C. to about 650° C. Moreover, the deposition of metal elements in the first and second set of elements can be done simultaneously or sequentially.

In some embodiments, the absorber layer 130 is completely formed onto substrate 110 after step 713. Moreover, in some embodiments, in steps 712 and 713, the sputtering and evaporation rates can vary throughout the deposition process or remain constant, wherein the rates can be controlled by, for example, control system 214. Similarly, the temperature within second deposition chamber 618 can remain constant or vary throughout the deposition process, wherein the temperature can also be controlled by control system 214.

In step 714, the layer 130 and substrate 110 are delivered to post-processing chamber 620 (shown in FIG. 6). In step 716, layer 130 and substrate 110 undergo cooling and/or annealing in post-processing chamber 620, wherein post-processing chamber 620 uses inert gas atmosphere with or without selenium, sulfur, and/or sulfur (chalcogen). In some embodiments, hydrogen gas can also be added to post-processing chamber 620 for the annealing. While some embodiments show post-processing chamber 620 using selenium, sulfur, hydrogen gas, and/or sulfur (chalcogen), it should be noted that any of the transfer chambers for apparatus 600 can also use such components to control the atmosphere within each of the chambers.

Layer 130 and substrate 110 can then be delivered to load lock 606 (shown in FIG. 6) in step 717, wherein layer 130 on substrate 110 can be prepared for the atmosphere in step 718. Moreover, in some embodiments, operational parameters within each of the chambers of apparatus 600 can be controlled independently via control system 214 (shown in FIG. 2). More specifically, a user can initially input a predefined threshold value for an operational parameter for each of the chambers. For example, a user can initially input a predefined threshold value for a temperature or a pressure for each of the chambers via input interface 260 (shown in FIG. 2). The predefined threshold value can be programmed with user computing device 250 and/or controller 220. As such, during operation of apparatus 600 and each of the chambers therein, the parameters, such as temperature and pressure, within each of the chambers can be detected by the sensors (not shown) coupled within each respective chamber. The sensors then transmit signal(s) representative of the detected parameter values to controller 220 (shown in FIG. 2).

Depending on whether the detected value is less than, greater than, or equal to the predefined threshold values for each of the chambers in apparatus 600, controller 220 will transmit a control parameter to each of the chambers. For example, in some embodiments, if the temperature within first deposition chamber 614 exceeds the predefined temperature value, controller 220 will transmit a control parameter to, for example, a heat exchanger (not shown) within deposition chamber 614 or heater (not shown) within deposition chamber 614 such that the temperature can be substantially reduced to the predefined temperature value. Similarly, if the pressure within for example, second transfer chamber 616 exceeds the predefined pressure values, controller 220 will transmit a control parameter to, for example, a valve (not shown) within transfer chamber 616 to control the fluid flow within transfer chamber 616 and/or use selenium, sulfur, hydrogen gas, and/or sulfur (chalcogen) to control the pressure within transfer chamber 616.

In some embodiments, a method includes providing heat to a substrate in at least one buffer chamber and transferring the substrate to at least one deposition chamber that is coupled to the buffer chamber via a conveyor. The method also includes depositing a first set of a plurality of elements, using sputtering, and a second set of a plurality of elements, using evaporation, onto at least a portion of the substrate in the deposition chamber.

In some embodiments, an apparatus for forming a chalcopyrite layer onto a substrate includes at least one buffer chamber that is configured to receive a substrate and to provide heat to the substrate. The apparatus also includes at least one deposition chamber that is coupled to the buffer chamber via a conveyor. The deposition chamber is configured to receive the substrate and to deposit a first set of a plurality of elements onto at least a portion of the substrate using sputtering and to deposit a second set of a plurality of elements onto at least a portion of the substrate using evaporation to form a chalcopyrite layer on the substrate.

In some embodiments, a method includes transferring a substrate from a buffer chamber to a first deposition chamber via a conveyor. The method also includes depositing at least a portion of a first set of a plurality of elements, using sputtering, and at least a portion of a second set of a plurality of elements, using evaporation, onto at least a portion of the substrate in the first deposition chamber at a first predefined temperature such that a first precursor layer is deposited onto the substrate. The substrate is transferred from the first deposition chamber to a second deposition chamber. Moreover, the method includes depositing at least a portion of the first set of elements, using sputtering, and at least a portion of the second set of elements, using evaporation, onto at least a portion of the substrate in the second deposition chamber at a second predefined temperature such that a second precursor layer is deposited onto the substrate.

Although the apparatus and method described herein have been described in terms of exemplary embodiments, they are not limited thereto. Rather, the appended claims should be construed broadly, to include other variants and embodiments of the disclosed system and method, which can be made by those skilled in the art without departing from the scope and range of equivalents of the system and method.

1. A method for forming a chalcopyrite layer onto a substrate, said method comprising:
providing heat to a substrate in at least one buffer chamber;
transferring the substrate to at least one deposition chamber that is coupled to the at least one buffer chamber via a conveyor; and
depositing, simultaneously, a first set of a plurality of elements, using sputtering, and a second set of a plurality of elements, using evaporation, onto at least a portion of the substrate in the at least one deposition chamber.

2. The method of claim 1, wherein depositing, simultaneously, the first set of a plurality of elements comprises depositing at least one of copper, zinc, indium, aluminum, gold, and tin, and depositing the second set of a plurality of elements includes depositing at least one of gallium, selenium, sulfur, and sodium, using evaporation.

3. The method of claim 1, wherein during the depositing, the substrate has a temperature range of from about 200° C. to about 650° C.

4. The method of claim 1, further comprising processing the chalcopyrite layer formed on the substrate in at least one post-processing chamber that is coupled to the at least one deposition chamber via the conveyor, wherein the at least one post-processing chamber includes one of an inert gas, selenium, sulfur, or hydrogen gas therein.

5. The method of claim 1, wherein transferring the substrate to at least one deposition chamber further comprises transferring the substrate to at least one of a first deposition chamber, a second deposition chamber, and a third deposition chamber.

6. The method of claim 5, further comprising controlling at least one operational parameter within each of the first, second, and third deposition chambers independently of each other.

7. The method of claim 5, wherein:
the depositing is partially performed in the first deposition chamber at a first predefined temperature; and
the depositing is partially performed in the second deposition chamber at a second predefined temperature; and
the depositing is partially performed in the third deposition chamber at a third predefined temperature.

8. The method of claim 7, further comprising controlling, independently, each of the first, second, and third predefined temperatures within the first, second, and third deposition chambers, respectively.

9. An apparatus for forming a chalcopyrite layer onto a substrate, said apparatus comprising:
at least one buffer chamber that is configured to receive a substrate and to provide heat to the substrate; and
at least one deposition chamber coupled to said at least one buffer chamber via a conveyor, said at least one deposition chamber is configured to receive the substrate and said at least one deposition chamber is configured to simultaneously deposit a first set of a plurality of elements onto at least a portion of the substrate using sputtering and a second set of a plurality of elements onto at least a portion of the substrate using evaporation to form a chalcopyrite layer on the substrate.

10. The apparatus of claim 9, wherein the first set of the plurality of elements includes at least one of copper, zinc, indium, aluminum, gold, and tin.

11. The apparatus of claim 9, wherein the second set of the plurality of elements includes at least one of gallium, selenium, sulfur, and sodium.

12. The apparatus of claim 9, wherein said at least one deposition chamber is configured to simultaneously deposit each of the first and second set of the plurality of elements onto at least a portion of the substrate at a temperature range of between about 200° C. to about 650° C.

13. The apparatus of claim 9, further comprising at least one post-processing chamber coupled to said at least one deposition chamber via the conveyor, wherein said at least one post-processing chamber comprises one of an inert gas, selenium, or sulfur therein to process the chalcopyrite layer formed on the substrate.

14. The apparatus of claim 9, wherein said at least one deposition chamber comprises a first deposition chamber, a second deposition chamber, and a third deposition chamber, each of said first, second, and third deposition chambers are configured to simultaneously deposit at least a portion of the first set of the plurality of elements onto at least a portion of the substrate using sputtering and at least a portion of the second set of the plurality of elements onto at least a portion of the substrate using evaporation.

15. The apparatus of claim 14, further comprising a processor configured to independently control at least one operational parameter within each of said first, second, and third deposition chambers.

16. The apparatus of claim 14, further comprising a plurality of transfer chambers such that a first transfer chamber of the plurality of transfer chambers is positioned between said first and second deposition chambers and a second transfer chamber of the plurality of transfer chambers is positioned between said second and third deposition chambers.

17. A method for forming a chalcopyrite layer onto a substrate, said method comprising:
transferring a substrate from a buffer chamber to a first deposition chamber via a conveyor;
depositing, simultaneously, at least a portion of a first set of a plurality of elements, using sputtering, and at least a portion of a second set of a plurality of elements, using evaporation, onto at least a portion of the substrate in the first deposition chamber at a first predefined temperature such that a first precursor layer is deposited onto the substrate;
transferring the substrate from the first deposition chamber to a second deposition chamber; and
depositing, simultaneously, at least a portion of the first set of the plurality of elements, using sputtering, and at least a portion of the second set of a plurality of elements, using evaporation, onto at least a portion of the substrate in the second deposition chamber at a second predefined temperature such that a second precursor layer is deposited onto the substrate.

18. The method of claim 17, wherein the first precursor layer is a copper-rich precursor layer and wherein the second precursor layer is a copper-poor precursor layer.

19. The method of claim 17 further comprising annealing the first and second precursor layers using inert gas.

20. The method of claim 19, wherein the first predefined temperature includes a temperature range of between about 400° C. to about 450° C. and wherein the second predefined temperature includes a temperature range of between about 500° C. to about 650° C.
